(19) United States
(12) Patent Application Publication
(10) Pub. No.: US 2022/0269842 A1
(43) Pub. Date: Aug. 25, 2022

(54) ESTIMATING EMISSIONS WITH VIRTUAL SENSOR MODELS

(71) Applicant: Microsoft Technology Licensing, LLC, Redmond, WA (US)

(72) Inventors: Mehmet Kadri UMAY, Redmond, WA (US); Imran SIDDIQUE, Bellevue, WA (US); Hari Krishnan SRINIVASAN, Redmond, WA (US); Nayana Singh PATEL, Mercer Island, WA (US); Jyothsna Devi BIJJAM, Redmond, WA (US)

(73) Assignee: Microsoft Technology Licensing, LLC, Redmond, WA (US)

(21) Appl. No.: 17/307,974

(22) Filed: May 4, 2021

Related U.S. Application Data
(60) Provisional application No. 63/151,609, filed on Feb. 19, 2021.

(51) Int. Cl. G06F 30/27; G06F 16/27; G06N 5/04; G05B 17/02; G06F 3/0482; G06F 3/0484

(52) U.S. Cl. CPC G06F 30/27; G06F 16/27; G06N 5/04; G05B 17/02; G06F 3/0482; G06F 3/04847; G06F 3/04817

(57) ABSTRACT

A computing device including a processor is provided. For one or more emissions factors, the processor may be configured to receive respective emissions factor data including sensor data received from one or more sensors and user-specified data received at a user interface. The processor may be further configured to receive a plurality of virtual sensor models. Each virtual sensor model may include one or more respective virtual sensor model parameters. At least in part by applying the virtual sensor models to the emissions factor data, the processor may be further configured to compute a plurality of virtual sensor readouts. The processor may be further configured to generate a greenhouse gas emissions estimate from the virtual sensor readouts. The processor may be further configured to convey an indication of the greenhouse gas emissions estimate to the user interface for output on one or more output devices.

### CROSS REFERENCE TO RELATED APPLICATIONS

This application claims priority to U.S. Provisional Patent Application Ser. No. 63/151,609, filed Feb. 19, 2021, the entirety of which is hereby incorporated herein by reference for all purposes.

### BACKGROUND

Estimation of greenhouse gas emissions has grown in importance as businesses and regulatory bodies have implemented efforts to reduce climate change. Estimating greenhouse gas emissions typically includes applying an estimation model developed by a standards-setting organization (such as an industry organization or government agency) to data specific to a particular greenhouse gas emitter (e.g. a business in the energy industry).

Estimation of greenhouse gas emissions using a model laid out by a standards-setting organization is typically performed by a user affiliated with the emitter using tools specific to that emitter. Accordingly, the estimation results may be expressed in a form that is difficult for the standards-setting organization to monitor or verify. In addition, since the formatting of such estimates is not standardized between different emitters, it may be difficult to use data included in the greenhouse gas emissions estimates as input for estimating other quantities.

### SUMMARY

According to one aspect of the present disclosure, a computing device including a processor is provided. For one or more emissions factors, the processor may be configured to receive respective emissions factor data including sensor data received from one or more sensors and user-specified data received at a user interface. The processor may be further configured to receive a plurality of virtual sensor models via an application program interface (API). Each virtual sensor model of the plurality of virtual sensor models may include one or more respective virtual sensor model parameters and may be configured to process the emissions factor data. At least in part by applying the plurality of virtual sensor models to the emissions factor data, the processor may be further configured to compute a plurality of virtual sensor readouts. The processor may be further configured to generate a greenhouse gas emissions estimate from the plurality of virtual sensor readouts. The processor may be further configured to convey an indication of the greenhouse gas emissions estimate to the user interface for output on one or more output devices.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 schematically shows a computing device, one or more sensors, a client computing device, and a model specifier computing device, according to one example embodiment.

FIG. 2 schematically shows the computing device, one or more sensors, client computing device, and model specifier computing device of FIG. 1 when a ledger is stored in the memory of the computing device, according to one example.

FIG. 3 shows an example user interface that may be displayed at the client computing device, according to the example of FIG. 1.

FIG. 4 schematically shows the computing device, one or more sensors, client computing device, and model specifier computing device of FIG. 1 when the computing device receives a virtual sensor model update, according to the example of FIG. 1.

FIG. 5 schematically shows the sensors of FIG. 1 in additional detail, including one or more physical sensors and one or more additional virtual sensor models, according to one example.

FIG. 6 schematically shows the computing device of FIG. 1 when the computing device is communicatively coupled to an industrial control system, according to one example.

FIG. 7A shows a flowchart of an example method that may be used with a computing device to generate and output a greenhouse gas emissions estimate, according to the example of FIG. 1.

FIGS. 7B-7D shows additional steps of the method of FIG. 6A that may be performed in some examples.

FIG. 8 shows a schematic view of an example computing environment in which the computing device of FIG. 1 may be enacted.

### DETAILED DESCRIPTION

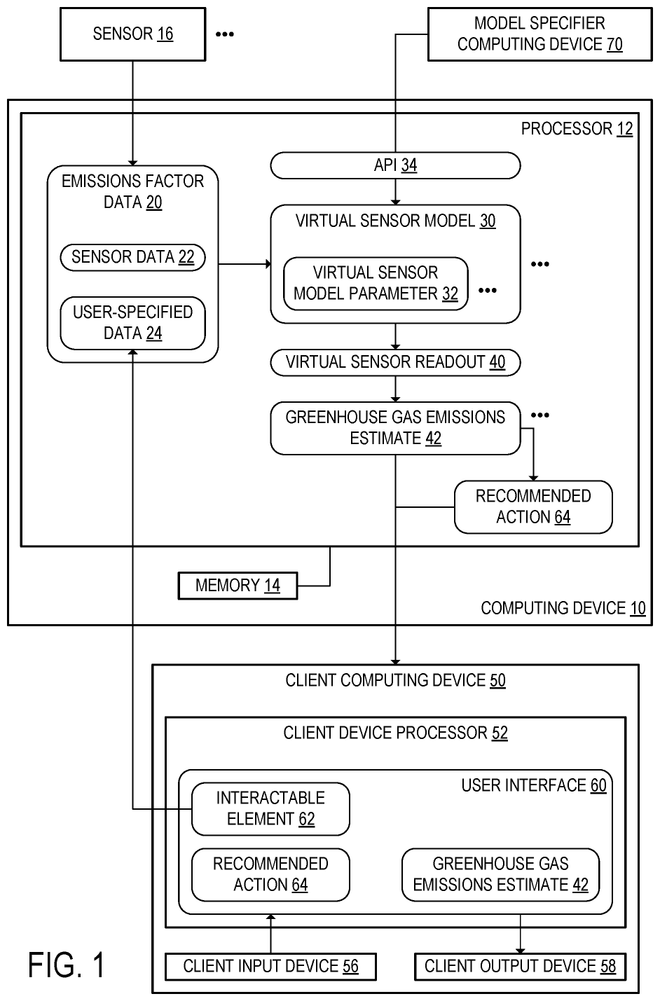

In order to address the challenges discussed above, a computing device 10 is provided, as schematically depicted in FIG. 1 according to one example embodiment. As shown in FIG. 1, the computing device 10 may include a processor 12 and memory 14. The computing device 10 may be configured to communicate with one or more other computing devices, such as the client computing device 50 and the model specifier computing device 70 also shown in FIG. 1. For example, the computing device 10 may be a server computing device. The computing device 10 may further include other hardware components not shown in FIG. 1, such as one or more input devices or one or more output devices.

In some examples, the computing device 10 may be instantiated in a plurality of communicatively linked computing devices rather than in a single physical computing device. For example, components of the computing device 10 may be distributed between a plurality of physical computing devices located in a data center and connected via a wired network. Processes executed at the processor 12 may be distributed between the respective processors of the plurality of communicatively linked computing devices. In addition, data stored in the memory 14 may be distributed between a plurality of memory devices located at different physical devices.

The processor 12 may be configured to receive emissions factor data 20 for one or more respective emissions factors. The one or more emissions factors may be used as variables for which data used to compute emissions estimates is collected. The one or more emissions factors may be numerical variables or categorical variables. For example, the one or more emissions factors may account for both greenhouse gas emissions that are directly produced by an emitter and greenhouse gas emissions that occur indirectly as a result of an emitter's activities.

The emissions factor data 20 may include sensor data 22 received from one or more sensors 16. In addition, the emissions factor data 20 may further include user-specified data 24 received at a user interface 60. The user interface 60 from which the processor 12 receives the user-specified data 24 may be executed at a client device processor 52 of the client computing device 50. The user interface 60 may be presented at one or more client output devices 58, and may, for example, be a graphical user interface (GUI) displayed on a display. The user interface 60 may include one or more interactable elements 62 via which the user of the client computing device 50 may enter the user-specified data 24 using one or more client input devices 56.

The emissions factors for which the emissions factor data 20 is received may indicate Scope 1, Scope 2, or Scope 3 emissions. Scope 1 emissions are emissions that occur as direct consequences of activities owned or controlled by the emitter organization. Scope 2 emissions are emissions associated with electricity, heat, steam, or cooling purchased by the emitter organization. Scope 3 emissions are emissions that occur indirectly as results of the organization's activities at sources that the organization does not own or control, and which are not included in Scope 2. Example emissions factors for which sensor data 22 may be received include an amount of a fossil fuel consumed, an amount of a refrigerant used, an amount of the refrigerant released, an amount of electrical energy used, a flow rate of a fluid, a distance traveled by a vehicle, a time interval, a temperature, or a concentration of a gas. Example emissions factors for which user-specified data 24 may be received include an amount of a fossil fuel consumed, an amount of a refrigerant used, an amount of the refrigerant released, an amount of electrical energy used, an electrical energy source, a distance traveled by a vehicle, a fuel efficiency of a vehicle, a floor area of a building, an electrical energy intensity estimate for a building, a time interval, an estimated greenhouse gas emission quantity associated with manufacturing a purchased product, an estimated greenhouse gas emission quantity associated with manufacturing a sold product, an estimated greenhouse gas emission quantity associated with using a sold product, an estimated greenhouse gas emission quantity associated with end-of-life for a sold product, or an estimated greenhouse gas emission quantity associated with performing a sold service. It is understood that the above lists are not exhaustive and that the emissions factor data 20 may include sensor data 22 or user-specified data 24 for one or more other emissions factors.

As shown in the example of FIG. 1, an application program interface (API) 34 may be executed at the processor 12 of the computing device 10. Via the API 34, the processor 12 may be further configured to receive a plurality of virtual sensor models 30. The plurality of virtual sensor models 30 may be received from the model specifier computing device 70. At the model specifier computing device 70, a user affiliated with a standards-setting organization may define one or more of the virtual sensor models 30.

Each virtual sensor model 30 of the plurality of virtual sensor models 30 may be configured to process the emissions factor data 20 received for the one or more respective emissions factors that act as the input variables for that virtual sensor model 30. Each virtual sensor model 30 of the plurality of virtual sensor models 30 may further include one or more respective virtual sensor model parameters 32 that are used to weight the emissions factor data 20. For example, the virtual sensor model 30 may be a linear combination of the emissions factor data 20 for a plurality of emissions factors weighted using the virtual sensor model parameters 32 according to the extent to which those emissions factors are estimated to contribute to total greenhouse gas emissions. In other examples, the emissions factor data 20 may be used as inputs for a nonlinear function specified by the virtual sensor model 30.

In some examples, as shown in FIG. 1, the model specifier computing device 70 from which the processor 12 receives the virtual sensor model 30 may differ from the client computing device 50. In such examples, the client computing device 50 may be prevented from modifying the respective virtual sensor model parameters 32 of the plurality of virtual sensor models 30. Thus, the standards-setting organization may present a standardized set of virtual sensor models 30 for use by greenhouse gas emitters. In other examples, the virtual sensor model 30 may be received from the client computing device 50.

The processor 12 may be further configured to compute a plurality of virtual sensor readouts 40 at least in part by applying the plurality of virtual sensor models 30 to the emissions factor data 20. Subsequently to computing the plurality of virtual sensor readouts 40, the processor 12 may be further configured to generate a greenhouse gas emissions estimate 42 from the plurality of virtual sensor readouts 40. The greenhouse gas emissions estimate 42 may indicate a total amount of at least one greenhouse gas estimated to be released as a result of activities indicated by the emissions factor data 20. For example, a greenhouse gas emissions estimate 42 may be computed for carbon dioxide, methane, hydrofluorocarbons, perfluorocarbons, sulfur hexafluoride, or nitrogen trifluoride. In some examples, the virtual sensor readouts 40 may be emissions estimates for particular greenhouse gases or greenhouse gas sources. In such examples, the processor 12 may be configured to sum the virtual sensor readouts 40 to compute the greenhouse gas emissions estimate 42. Alternatively, at least one of the virtual sensor readouts 40 may represent a quantity other than an amount of a greenhouse gas emitted (e.g. a total amount of electrical energy consumed at a building). In examples in which at least one virtual sensor readout 40 indicates a quantity other than an amount of a greenhouse gas emitted, the processor 12 may be further configured to perform further computation on that virtual sensor readout 40 when computing the greenhouse gas emissions estimate 42.

The processor 12 may be further configured to convey an indication of the greenhouse gas emissions estimate 42 to the user interface 60 for output on one or more output devices. As discussed above, the user interface 60 may be presented via one or more client output devices 58 included in the client computing device 50. Additionally or alternatively to the greenhouse gas emissions estimate 42, the processor 12 may be configured to convey one or more virtual sensor readouts 40 to the user interface 60 for output on the one or more output devices.

In some examples, the processor 12 may be further configured to select a recommended action 64 based at least in part on the greenhouse gas emissions estimate 42. In such examples, the processor 12 may be further configured to convey an indication of the recommended action 64 to the user interface 60 for output on the one or more output devices 58. In one example, the indication of the recommended action 64 may be a recommendation to utilize a particular vehicle included in a fleet of vehicles. The recommended vehicle may, in this example, be located closer to a destination or may have higher fuel efficiency compared to other vehicles included in the fleet. It will be appreciated that a wide variety of other recommended actions may alternatively be presented.

In some examples, the greenhouse gas emissions estimate 42 may indicate a predicted amount of a greenhouse gas emission associated with a transaction. The transaction may be a transaction that has already been performed by the user of the client computing device 50. For example, the user may estimate the greenhouse gas emissions associated with a transaction in order to satisfy an emissions reporting requirement. Alternatively, the greenhouse gas emissions estimate 42 may be conveyed to the user interface 60 prior to the user performing the transaction. The user may therefore review an estimated amount of greenhouse gas emissions associated with a potential transaction, which may inform the user's decision about whether to perform the transaction. As another example, the user interface 60 may provide the user with an option to sell or purchase renewable energy credits based on the greenhouse gas emissions estimate 42. In examples in which the processor 12 is configured to convey an indication of a recommended action 64 to the user interface 60, the recommended action 64 may be performing the transaction or not performing the transaction.

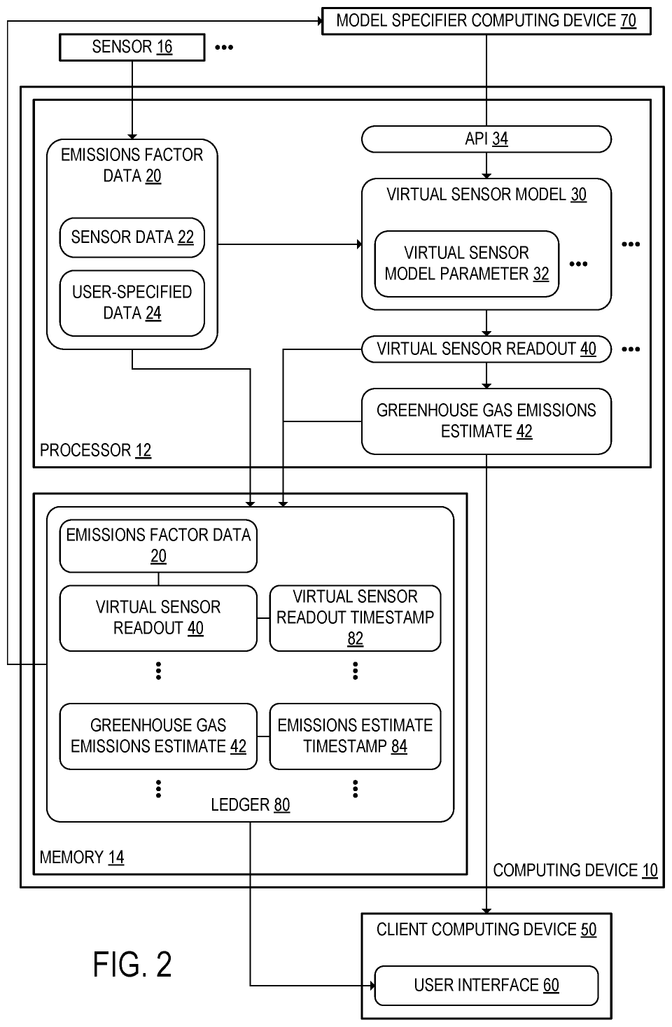

Turning now to FIG. 2, the memory 14 of the computing device 10 may be configured to store a ledger 80 including the plurality of virtual sensor readouts 40. In addition, the ledger 80 may further include corresponding virtual sensor readout timestamps 82 for the plurality of virtual sensor readouts 40. The ledger 80 may further store greenhouse gas emissions estimates 42 and corresponding emissions estimate timestamps 84. Thus, the memory 14 may store timestamped historical records of the virtual sensor readouts 40 and the greenhouse gas emissions estimates 42. In some examples, emissions factor data 20 including the sensor data 22 and/or the user-specified data 24 that is used as input for a virtual sensor 30 may also be stored in the ledger 80. Such emissions factor data 20 may be associated with the virtual sensor readout timestamps 82 of the virtual sensor readouts 40 output by the virtual sensor 30.

Contents of the ledger 80, including one or more virtual sensor readouts 40, one or more greenhouse gas emissions estimates 42, sensor data 22, user-specified data 24, one or more virtual sensor readout timestamps 82, and/or one or more emissions estimate timestamps 84, may be conveyed to the client computing device 50 for output at the user interface 60. Additionally or alternatively, contents of the ledger 80 may be conveyed to the model specifier computing device 70 for auditing by a member of the standards-setting organization. Thus, the virtual sensor readouts 40 and the greenhouse gas emissions estimates 42 may be presented in a standardized form to other computing devices. Storing the virtual sensor readouts 40 and the greenhouse gas emissions estimates 42 in the ledger 80 may allow the virtual sensor readouts 40 and the greenhouse gas emissions estimates 42 to be more easily monitored and audited.

Using the ledger 80 to standardize the formatting of the virtual sensor readouts 40 and the greenhouse gas emissions estimates 42 may further allow the virtual sensor readouts 40 and the greenhouse gas emissions estimates 42 to be used as training data in machine learning applications. In some examples, at least one virtual sensor model 30 of the plurality of virtual sensor models 30 may be a machine learning model. In such examples, the machine learning model may be trained using historical measurements of the one or more emissions factors used as inputs for the at least one virtual sensor model 30, as well as historical measurements of the one or more quantities indicated by the virtual sensor readouts 40 of the at least one virtual sensor model 30. The historical data used to train the machine learning model may include the emissions factor data 20, the virtual sensor readouts 40, and/or the greenhouse gas emissions estimates 42 stored in the ledger 80.

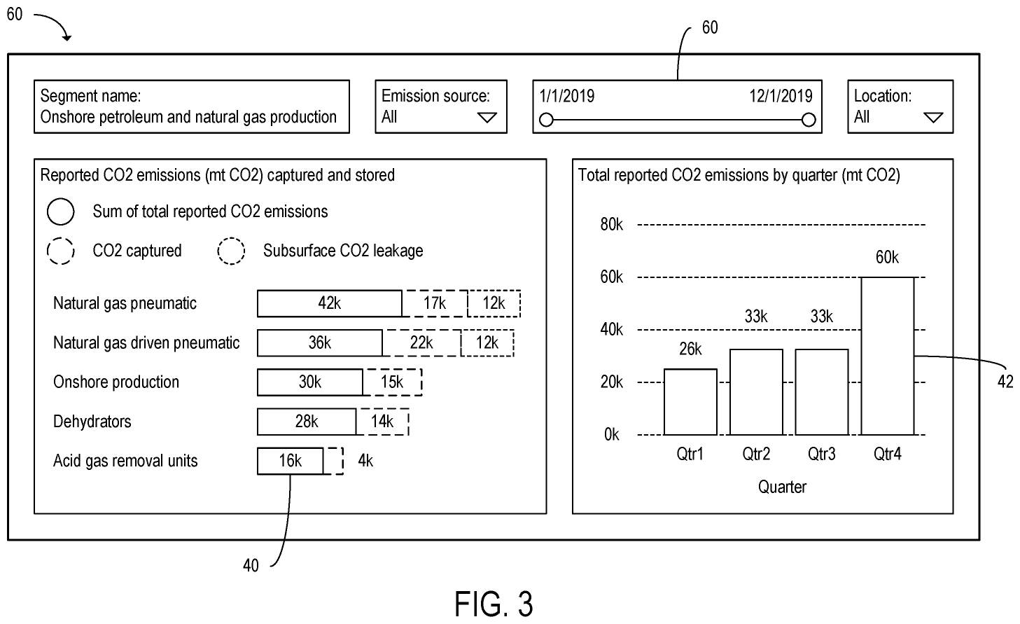

FIG. 3 shows an example of the user interface 60 when a plurality of virtual sensor readouts 40 and a plurality of greenhouse gas emissions estimates 42 are displayed. In the example of FIG. 3, the virtual sensor readouts 40 include “Sum of total reported CO2 emissions,” “CO2 captured,” and “Subsurface CO2 leakage” for each of the categories “Natural gas pneumatic,” “Natural gas driven pneumatic,” “Onshore production,” “Dehydrators,” and “Acid gas removal units.” In addition, a respective greenhouse gas emissions estimate 42 is shown for each quarter of 2019. The user interface of FIG. 3 further includes a plurality of interactable elements 62, including drop down menu display icons and a slider bar for selecting a time interval. The user may select the user-specified data 24 at least in part using these interactable elements 62.

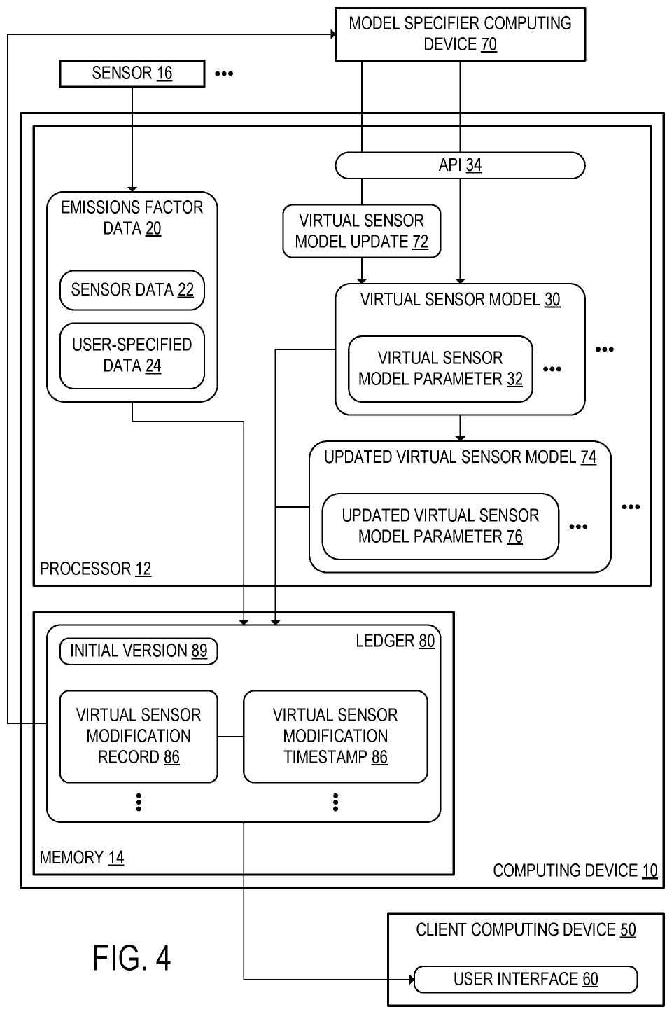

As shown in FIG. 4, the processor 12 may be further configured to receive a virtual sensor model update 72 via the API 34. The virtual sensor model update 72 may be received from the model specifier computing device 70. The processor 12 may be further configured to modify a virtual sensor model 30 of the plurality of virtual sensor models 30 as specified by the virtual sensor model update 72. For example, the virtual sensor model update 72 may specify one or more updated values of one or more of the virtual sensor model parameters 32 of the virtual sensor model 30. Thus, the processor 12 may be configured to apply the virtual sensor model update 72 to the virtual sensor model 30 to generate an updated virtual sensor model 74 with one or more updated virtual sensor model parameters 76. When the virtual sensor model 30 is a machine learning model, applying the virtual sensor model update 72 may include performing additional training at the machine learning model. In some examples, a virtual sensor model update 72 may be used to update a plurality of the virtual sensor models 30.

In response to modifying the virtual sensor model 30, the processor 12 may be further configured to store, in the ledger 80, a virtual sensor modification record 86 corresponding to the virtual sensor model update 72. The virtual sensor modification record 86 may be a copy of the updated virtual sensor model 74 in some examples. Alternatively, the virtual sensor modification record 86 may indicate one or more changes to the virtual sensor model 30 without including the entire updated virtual sensor model 74. In addition, the processor 12 may be further configured to store, in the ledger 80, a virtual sensor modification timestamp 88 for the virtual sensor modification record 86. The virtual sensor modification timestamp 88 for a virtual sensor modification record 86 may indicate a time at which the corresponding virtual sensor model update 72 was applied. The ledger 80 may further store an indication of an initial version 89 of the virtual sensor model 30 prior to the application of any virtual sensor model updates 72. Thus, the virtual sensor model 30 at any given time after its initial creation may be reconstructed based on the initial version 89, the virtual sensor model updates 72, and the virtual sensor modification timestamps 88 stored in the ledger 80.

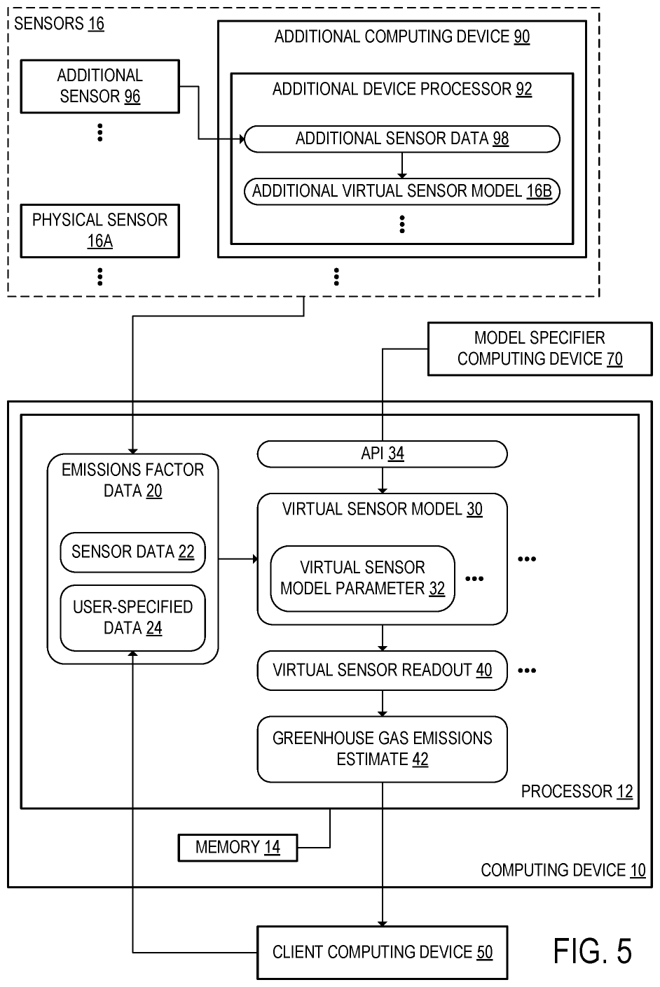

Turning now to FIG. 5, the one or more sensors 16 from which the processor 12 receives the sensor data 22 are shown in additional detail. In the example of FIG. 5, the one or more sensors 16 include one or more physical sensors 16A. The one or more physical sensors 16A may be located separately from the computing device 10 and may be configured to transmit sensor data 22 to the processor 12 via a wired or wireless connection. For example, the one or more physical sensors 16A may be located in one or more Internet of Things (IoT) connected devices configured to communicate with the computing device 10. In other examples, at least one of the one or more physical sensors 16A may be included in the computing device 10. For example, a physical sensor 16A included in the computing device 10 may be configured to measure energy consumption by the computing device 10.

The one or more sensors 16 shown in the example of FIG. 5 further include one or more additional virtual sensor models 16B. The readouts of the one or more additional virtual sensor models 16B may be included in the sensor data 22 along with measurements taken at the one or more physical sensors 16A. Thus, a virtual sensor model 30 may be used as though it were a physical sensor 16A when the processor 12 receives the emissions factor data 20. The one or more additional virtual sensor models 16B may be executed at an additional device processor 92 of an additional computing device 90. The additional computing device 90 may be configured to receive, from one or more additional sensors 96, additional sensor data 98 that is used as input data for the one or more additional virtual sensor models 16B. The one or more additional sensors 96 may include one or more physical sensors 16A and/or one or more additional virtual sensor models 16B. Thus, the inputs and outputs of additional virtual sensor models 16B may be chained together, with some steps in the chain additionally including one or more physical sensors 16A as inputs. The outputs of virtual sensor models may therefore be integrated into estimates of greenhouse gas emissions computed by other users more easily than non-standardized data related to emissions factors.

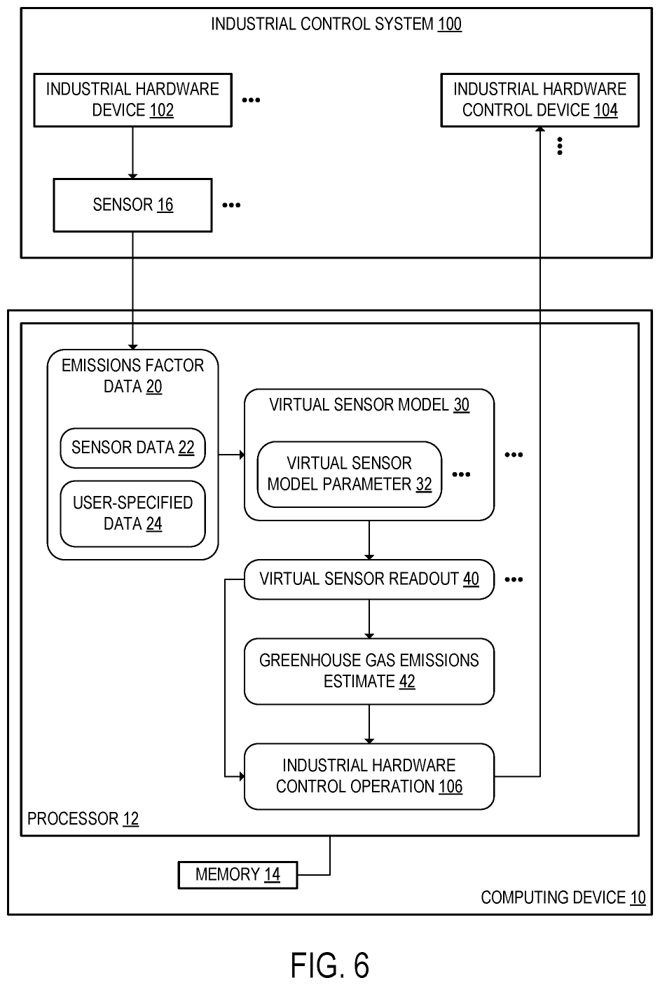

In some examples, as schematically shown in FIG. 6, the computing device 10 may be communicatively coupled to an industrial control system 100. The industrial control system 100 may be configured to provide programmatic control for an industrial process performed at one or more industrial hardware devices 102. For example, the industrial process may be a manufacturing process, a resource extraction process, a waste disposal process, a power generation process, or some combination thereof. In the example of FIG. 6, the one or more sensors 16 may be configured to collect the sensor data 22 from the one or more industrial hardware devices 102. For example, a sensor 16 of the one or more sensors 16 may be configured to measure electrical power consumption at an industrial hardware device 102. As another example, a sensor 16 of the one or more sensors 16 may be configured to measure a flow rate of a fluid through an industrial hardware device 102.

In the example of FIG. 6, the processor 12 may be further configured to programmatically determine an industrial hardware control operation 106 based at least in part on the greenhouse gas emissions estimate 42. The industrial hardware control operation 106 may additionally or alternatively be determined based at least in part on the plurality of virtual sensor readouts 40 treated separately from the greenhouse gas emissions estimate 42. In some examples, the processor 12 may be configured to determine the industrial hardware control operation 106 without user intervention. The processor 12 may be further configured to output instructions to perform the industrial hardware control operation 106 to one or more industrial hardware control devices 104 coupled to the industrial hardware devices 102. According to one example, the industrial hardware control operation 106 may be an operation to decrease an amount of electrical power supplied to an industrial hardware device 102 when the greenhouse gas emissions estimate 42 is above a predetermined threshold.

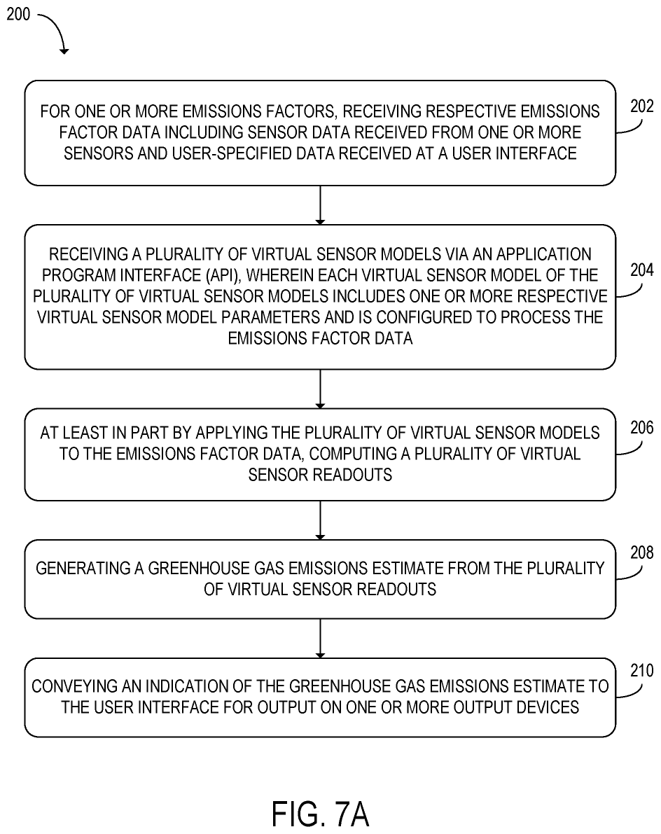

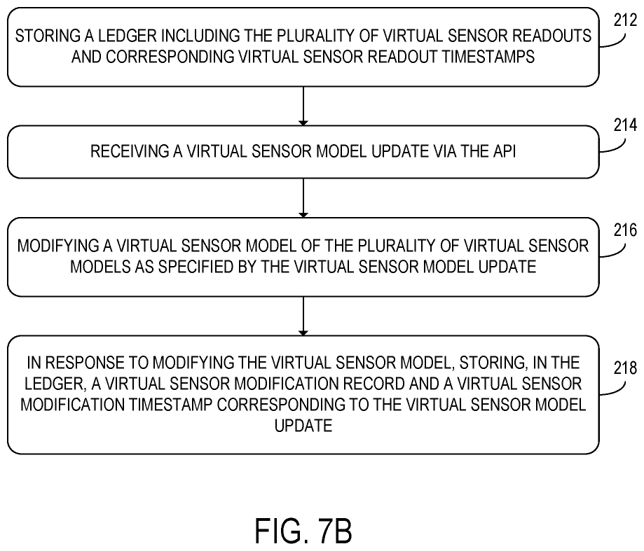

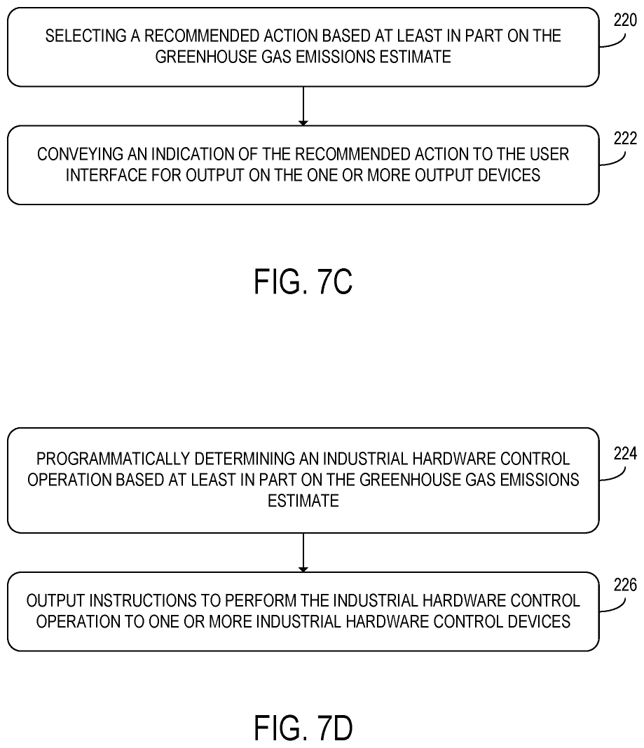

FIG. 7A shows a flowchart of an example method 200 that may be performed at a computing device to generate and output a greenhouse gas emissions estimate. The method 200 may be performed at the computing device 10 of FIG. 1 or at some other computing device. At step 202, the method 200 may include receiving respective emissions factor data for one or more emissions factors. The one or more emissions factors are variables from which greenhouse gas emissions may be computed. The emissions factor data may include sensor data received from one or more sensors. The sensor data may, for example, include at least one of an amount of a fossil fuel consumed, an amount of a refrigerant used, an amount of the refrigerant released, an amount of electrical energy used, a flow rate of a fluid, a distance traveled by a vehicle, a time interval, a temperature, or a concentration of a gas. Sensor data may additionally or alternatively be received for emissions factors other than those listed above.

The emissions factor data may further include user-specified data received at a user interface, which may be presented at a client computing device configured to communicate with the computing device at which the method 200 is performed. For example, the user-specified data may include at least one of an amount of a fossil fuel consumed, an amount of a refrigerant used, an amount of the refrigerant released, an amount of electrical energy used, an electrical energy source, a distance traveled by a vehicle, a fuel efficiency of a vehicle, a floor area of a building, an electrical energy intensity estimate for a building, a time interval, an estimated greenhouse gas emission quantity associated with manufacturing a purchased product, an estimated greenhouse gas emission quantity associated with manufacturing a sold product, an estimated greenhouse gas emission quantity associated with using a sold product, an estimated greenhouse gas emission quantity associated with end-of-life for a sold product, or an estimated greenhouse gas emission quantity associated with performing a sold service. User-specified data may additionally or alternatively be received for emissions factors other than those listed above.

At step 204, the method 200 may further include receiving a plurality of virtual sensor models via an API. Each virtual sensor model of the plurality of virtual sensor models may include one or more respective virtual sensor model parameters and may be configured to process the emissions factor data. The plurality of virtual sensor models may, for example, be received from a model specifier computing device at which a user affiliated with a standards-setting organization may define the plurality of virtual sensor models. In such examples, the model specifier computing device may differ from the client computing device, and the client computing device may be prevented from modifying the respective virtual sensor model parameters of the plurality of virtual sensor models. In some examples, at least one virtual sensor model of the plurality of virtual sensor models may be a machine learning model.

At step 206, the method 200 may further include computing a plurality of virtual sensor readouts at least in part by applying the plurality of virtual sensor models to the emissions factor data. Each virtual sensor readout may be an emissions estimate or an intermediate quantity from which an emissions estimate may be computed. At step 208, the method 200 may further include generating a greenhouse gas emissions estimate from the plurality of virtual sensor readouts. For example, the greenhouse gas emissions estimate may be a sum of a plurality of emissions estimates computed for a corresponding plurality of activities at respective virtual sensor models. In some examples, the one or more sensors may include one or more physical sensors and one or more additional virtual sensor models. Thus, outputs of an additional virtual sensor may be incorporated into the emissions factor data as though they were outputs of a physical sensor.

At step 210, the method 200 may further include conveying an indication of the greenhouse gas emissions estimate to the user interface for output on one or more output devices. In some examples, the greenhouse gas emissions estimate indicates a predicted amount of a greenhouse gas emission associated with a transaction. The transaction may be a sale or purchase made by the user. In such examples, the greenhouse gas emissions estimate may be conveyed to the user interface prior to the user performing the transaction. Thus, the user may account for estimated greenhouse gas emissions when deciding whether to make the transaction. Alternatively, the greenhouse gas emissions estimate for a transaction may be computed after the transaction has occurred.

FIGS. 7B-7D show additional steps of the method 200 that may be performed in some examples. At step 212, the method 200 may further include storing a ledger including the plurality of virtual sensor readouts and corresponding virtual sensor readout timestamps. The ledger may be stored in memory included in the computing device at which the method 200 is performed. In addition, one or more greenhouse gas emissions estimates may be stored in the ledger. In some examples, the ledger may further store the emissions factor data used as the inputs by the plurality of virtual sensor models for which virtual sensor readouts are stored in the ledger.

At step 214, the method 200 may further include receiving a virtual sensor model update via the API. The virtual sensor model update may be received from the model specifier computing device. At step 216, the method 200 may further include modifying a virtual sensor model of the plurality of virtual sensor models as specified by the virtual sensor model update. For example, modifying a virtual sensor model may include changing the values of the virtual sensor model parameters of that virtual sensor model to obtain an updated virtual sensor model with updated virtual sensor model parameters. Additionally or alternatively, the virtual sensor model update may add or remove emissions factors. In some examples, when the virtual sensor model is a machine learning model, modifying the virtual sensor model as specified by the virtual sensor model update may include performing additional training at the machine learning model.

At step 218, the method 200 may further include storing, in the ledger, a virtual sensor modification record and a virtual sensor modification timestamp corresponding to the virtual sensor model update. The virtual sensor modification record and the virtual sensor modification timestamp may be stored in the ledger in response to modifying the virtual sensor model. In addition, an initial version of the virtual sensor model may be stored in the ledger prior to performing modifications to the virtual sensor model. Thus, the processor 12 may be configured to reconstruct historical versions of the virtual sensor model based on the data stored in the ledger.

FIG. 7C shows steps of the method 200 that may be performed subsequently to generating the greenhouse gas emissions estimate. At step 220, the method 200 may further include selecting a recommended action based at least in part on the greenhouse gas emissions estimate. At step 222, the method 200 may further include conveying an indication of the recommended action to the user interface for output on the one or more output devices. In examples in which the greenhouse gas emissions estimate is an estimate of emissions associated with a transaction, indication of the recommended action may be a recommendation to perform the transaction or to not perform the transaction.

FIG. 7D shows steps of the method 200 that may be performed in examples in which emissions factor data is collected for an industrial control process performed at one or more industrial hardware devices. For example, the industrial process may be a manufacturing process, a resource extraction process, a waste disposal process, a power generation process, or some combination thereof. At step 224, the method 200 may further include programmatically determining an industrial hardware control operation based at least in part on the greenhouse gas emissions estimate. In addition to the greenhouse gas emissions estimate, the industrial hardware control operation may be determined based at least in part on the plurality of virtual sensor readouts. The industrial hardware control operation may be determined without user intervention. At step 226, the method 200 may further include outputting instructions to perform the industrial hardware control operation to one or more industrial hardware control devices. Accordingly, the plurality of virtual sensors may be incorporated into a programmatic control system for an industrial process. Information related to greenhouse gas emissions associated with the industrial process may thereby be used when programmatic control of the industrial process is performed.

Using the devices and methods discussed above, greenhouse gas emissions may be estimated in a manner that is standardized between different emitters. Greenhouse gas emissions estimates made using the above devices and methods may be monitored and audited more easily by standards-setting organizations or by users within an emitter organization. In addition, the outputs of virtual sensor models may be used as inputs for other computations (e.g. training machine learning models) more easily than emissions estimates computed using previously existing methods.

In some embodiments, the methods and processes described herein may be tied to a computing system of one or more computing devices. In particular, such methods and processes may be implemented as a computer-application program or service, an application-programming interface (API), a library, and/or other computer-program product.

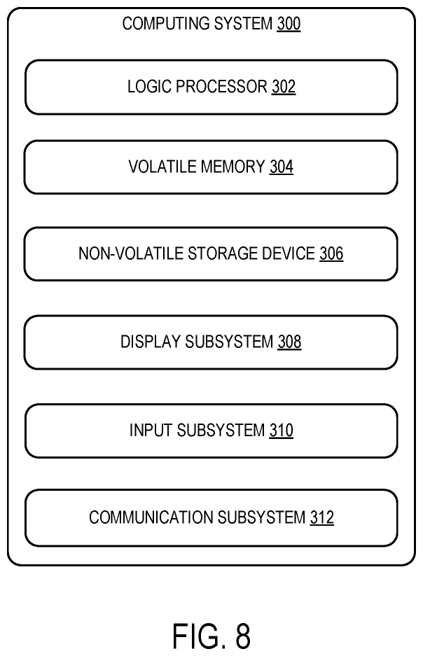

FIG. 8 schematically shows a non-limiting embodiment of a computing system 300 that can enact one or more of the methods and processes described above. Computing system 300 is shown in simplified form. Computing system 300 may embody the computing device 10 described above and illustrated in FIG. 1. Computing system 300 may take the form of one or more personal computers, server computers, tablet computers, home-entertainment computers, network computing devices, gaming devices, mobile computing devices, mobile communication devices (e.g., smart phone), and/or other computing devices, and wearable computing devices such as smart wristwatches and head mounted augmented reality devices.

Computing system 300 includes a logic processor 302 volatile memory 304, and a non-volatile storage device 306. Computing system 300 may optionally include a display subsystem 308, input subsystem 310, communication subsystem 312, and/or other components not shown in FIG. 8.

Logic processor 302 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors (hardware) configured to execute software instructions. Additionally or alternatively, the logic processor may include one or more hardware logic circuits or firmware devices configured to execute hardware-implemented logic or firmware instructions. Processors of the logic processor 302 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Non-volatile storage device 306 includes one or more physical devices configured to hold instructions executable by the logic processors to implement the methods and processes described herein. When such methods and processes are implemented, the state of non-volatile storage device 306 may be transformed—e.g., to hold different data.

Non-volatile storage device 306 may include physical devices that are removable and/or built-in. Non-volatile storage device 306 may include optical memory (e.g., CD, DVD, HD-DVD, Blu-Ray Disc, etc.), semiconductor memory (e.g., ROM, EPROM, EEPROM, FLASH memory, etc.), and/or magnetic memory (e.g., hard-disk drive, floppy-disk drive, tape drive, MRAM, etc.), or other mass storage device technology. Non-volatile storage device 306 may include nonvolatile, dynamic, static, read/write, read-only, sequential-access, location-addressable, file-addressable, and/or content-addressable devices. It will be appreciated that non-volatile storage device 306 is configured to hold instructions even when power is cut to the non-volatile storage device 306.

Volatile memory 304 may include physical devices that include random access memory. Volatile memory 304 is typically utilized by logic processor 302 to temporarily store information during processing of software instructions. It will be appreciated that volatile memory 304 typically does not continue to store instructions when power is cut to the volatile memory 304.

Aspects of logic processor 302, volatile memory 304, and non-volatile storage device 306 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 300 typically implemented in software by a processor to perform a particular function using portions of volatile memory, which function involves transformative processing that specially configures the processor to perform the function. Thus, a module, program, or engine may be instantiated via logic processor 302 executing instructions held by non-volatile storage device 306, using portions of volatile memory 304. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

When included, display subsystem 308 may be used to present a visual representation of data held by non-volatile storage device 306. The visual representation may take the form of a graphical user interface (GUI). As the herein described methods and processes change the data held by the non-volatile storage device, and thus transform the state of the non-volatile storage device, the state of display subsystem 308 may likewise be transformed to visually represent changes in the underlying data. Display subsystem 308 may include one or more display devices utilizing virtually any type of technology. Such display devices may be combined with logic processor 302, volatile memory 304, and/or non-volatile storage device 306 in a shared enclosure, or such display devices may be peripheral display devices.

When included, input subsystem 310 may comprise or interface with one or more user-input devices such as a keyboard, mouse, touch screen, or game controller. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity; and/or any other suitable sensor.

When included, communication subsystem 312 may be configured to communicatively couple various computing devices described herein with each other, and with other devices. Communication subsystem 312 may include wired and/or wireless communication devices compatible with one or more different communication protocols. As non-limiting examples, the communication subsystem may be configured for communication via a wireless telephone network, or a wired or wireless local- or wide-area network, such as a HDMI over Wi-Fi connection. In some embodiments, the communication subsystem may allow computing system 300 to send and/or receive messages to and/or from other devices via a network such as the Internet.

The following paragraphs discuss several aspects of the present disclosure. According to one aspect of the present disclosure, a computing device is provided, including a processor configured to, for one or more emissions factors, receive respective emissions factor data including sensor data received from one or more sensors and user-specified data received at a user interface. The processor may be further configured to receive a plurality of virtual sensor models via an application program interface (API). Each virtual sensor model of the plurality of virtual sensor models may include one or more respective virtual sensor model parameters and may be configured to process the emissions factor data. At least in part by applying the plurality of virtual sensor models to the emissions factor data, the processor may be further configured to compute a plurality of virtual sensor readouts. The processor may be further configured to generate a greenhouse gas emissions estimate from the plurality of virtual sensor readouts. The processor may be further configured to convey an indication of the greenhouse gas emissions estimate to the user interface for output on one or more output devices.

According to this aspect, the computing device may further include memory configured to store a ledger including the plurality of virtual sensor readouts and corresponding virtual sensor readout timestamps.

According to this aspect, the processor may be further configured to receive a virtual sensor model update via the API and modify a virtual sensor model of the plurality of virtual sensor models as specified by the virtual sensor model update.

According to this aspect, in response to modifying the virtual sensor model, the processor may be further configured to store, in the ledger, a virtual sensor modification record and a virtual sensor modification timestamp corresponding to the virtual sensor model update.

According to this aspect, the sensor data may include at least one of an amount of a fossil fuel consumed, an amount of a refrigerant used, an amount of the refrigerant released, an amount of electrical energy used, a flow rate of a fluid, a distance traveled by a vehicle, a time interval, a temperature, or a concentration of a gas.

According to this aspect, the user-specified data may include at least one of an amount of a fossil fuel consumed, an amount of a refrigerant used, an amount of the refrigerant released, an amount of electrical energy used, an electrical energy source, a distance traveled by a vehicle, a fuel efficiency of a vehicle, a floor area of a building, an electrical energy intensity estimate for a building, a time interval, an estimated greenhouse gas emission quantity associated with manufacturing a purchased product, an estimated greenhouse gas emission quantity associated with manufacturing a sold product, an estimated greenhouse gas emission quantity associated with using a sold product, an estimated greenhouse gas emission quantity associated with end-of-life for a sold product, or an estimated greenhouse gas emission quantity associated with performing a sold service.

According to this aspect, the one or more sensors may include one or more physical sensors and one or more additional virtual sensor models.

According to this aspect, at least one virtual sensor model of the plurality of virtual sensor models may be a machine learning model.

According to this aspect, the processor may be configured to receive the plurality of virtual sensor models from a model specifier computing device that differs from the client computing device. The client computing device may be prevented from modifying the respective virtual sensor model parameters of the plurality of virtual sensor models.

According to this aspect, the greenhouse gas emissions estimate may indicate a predicted amount of a greenhouse gas emission associated with a transaction. The greenhouse gas emissions estimate may be conveyed to the user interface prior to the user performing the transaction.

According to this aspect, the processor may be further configured to select a recommended action based at least in part on the greenhouse gas emissions estimate. The processor may be further configured to convey an indication of the recommended action to the user interface for output on the one or more output devices.

According to this aspect, the processor may be further configured to programmatically determine an industrial hardware control operation based at least in part on the greenhouse gas emissions estimate. The processor may be further configured to output instructions to perform the industrial hardware control operation to one or more industrial hardware control devices.

According to another aspect of the present disclosure, a method for use with a computing device is provided. The method may include, for one or more emissions factors, receiving respective emissions factor data including sensor data received from one or more sensors and user-specified data received at a user interface. The method may further include receiving a plurality of virtual sensor models via an application program interface (API). Each virtual sensor model of the plurality of virtual sensor models may include one or more respective virtual sensor model parameters and may be configured to process the emissions factor data. The method may further include, at least in part by applying the plurality of virtual sensor models to the emissions factor data, computing a plurality of virtual sensor readouts. The method may further include generating a greenhouse gas emissions estimate from the plurality of virtual sensor readouts. The method may further include conveying an indication of the greenhouse gas emissions estimate to the user interface for output on one or more output devices.

According to this aspect, the method may further include storing a ledger including the plurality of virtual sensor readouts and corresponding virtual sensor readout timestamps.

According to this aspect, the method may further include receiving a virtual sensor model update via the API. The method may further include modifying a virtual sensor model of the plurality of virtual sensor models as specified by the virtual sensor model update. In response to modifying the virtual sensor model, the method may further include storing, in the ledger, a virtual sensor modification record and a virtual sensor modification timestamp corresponding to the virtual sensor model update.

According to this aspect, the one or more sensors may include one or more physical sensors and one or more additional virtual sensor models.

According to this aspect, at least one virtual sensor model of the plurality of virtual sensor models may be a machine learning model.

According to this aspect, the plurality of virtual sensor models may be received from a model specifier computing device that differs from the client computing device. The client computing device may be prevented from modifying the respective virtual sensor model parameters of the plurality of virtual sensor models.

According to this aspect, the greenhouse gas emissions estimate indicates a predicted amount of a greenhouse gas emission associated with a transaction. The greenhouse gas emissions estimate may be conveyed to the user interface prior to the user performing the transaction.

According to another aspect of the present disclosure, a computing device is provided, including memory and a processor configured to, for one or more emissions factors, receive respective emissions factor data including sensor data received from one or more sensors and user-specified data received at a user interface. The processor may be further configured to receive a virtual sensor model. The virtual sensor model may include one or more respective virtual sensor model parameters and may be configured to process the emissions factor data. At least in part by applying the virtual sensor model to the emissions factor data, the processor may be further configured to compute a virtual sensor readout. The processor may be further configured to generate a greenhouse gas emissions estimate from the virtual sensor readout. The processor may be further configured to store, in the memory, a ledger including the virtual sensor readout and a corresponding virtual sensor readout timestamp. The processor may be further configured to convey the virtual sensor readout and the virtual sensor readout timestamp to the user interface for output on one or more output devices.

“And/or” as used herein is defined as the inclusive or v, as specified by the following truth table:

| A | B | A ∨ B |
|---|---|---|
| True | True | True |
| True | False | True |
| False | True | True |
| False | False | False |

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing device comprising:
a processor configured to:
for one or more emissions factors, receive respective emissions factor data including sensor data received from one or more sensors and user-specified data received at a user interface;
receive a plurality of virtual sensor models via an application program interface (API), wherein each virtual sensor model of the plurality of virtual sensor models includes one or more respective virtual sensor model parameters and is configured to process the emissions factor data;
at least in part by applying the plurality of virtual sensor models to the emissions factor data, compute a plurality of virtual sensor readouts;
generate a greenhouse gas emissions estimate from the plurality of virtual sensor readouts; and
convey an indication of the greenhouse gas emissions estimate to the user interface for output on one or more output devices.

2. The computing device of claim 1, further comprising memory configured to store a ledger including the plurality of virtual sensor readouts and corresponding virtual sensor readout timestamps.

3. The computing device of claim 2, wherein the processor is further configured to:
receive a virtual sensor model update via the API; and
modify a virtual sensor model of the plurality of virtual sensor models as specified by the virtual sensor model update.

4. The computing device of claim 3, wherein, in response to modifying the virtual sensor model, the processor is further configured to store, in the ledger, a virtual sensor modification record and a virtual sensor modification timestamp corresponding to the virtual sensor model update.

5. The computing device of claim 1, wherein the sensor data includes at least one of:
an amount of a fossil fuel consumed;
an amount of a refrigerant used;
an amount of the refrigerant released;
an amount of electrical energy used;
a flow rate of a fluid;
a distance traveled by a vehicle;
a time interval;
a temperature; or
a concentration of a gas.

6. The computing device of claim 1, wherein the user-specified data includes at least one of:
an amount of a fossil fuel consumed;
an amount of a refrigerant used;
an amount of the refrigerant released;
an amount of electrical energy used;
an electrical energy source;
a distance traveled by a vehicle;
a fuel efficiency of a vehicle;
a floor area of a building;
an electrical energy intensity estimate for a building;
a time interval;
an estimated greenhouse gas emission quantity associated with manufacturing a purchased product;
an estimated greenhouse gas emission quantity associated with manufacturing a sold product;
an estimated greenhouse gas emission quantity associated with using a sold product;
an estimated greenhouse gas emission quantity associated with end-of-life for a sold product; or
an estimated greenhouse gas emission quantity associated with performing a sold service.

7. The computing device of claim 1, wherein the one or more sensors include one or more physical sensors and one or more additional virtual sensor models.

8. The computing device of claim 1, wherein at least one virtual sensor model of the plurality of virtual sensor models is a machine learning model.

9. The computing device of claim 1, wherein:
the processor is configured to receive the plurality of virtual sensor models from a model specifier computing device that differs from the client computing device; and
the client computing device is prevented from modifying the respective virtual sensor model parameters of the plurality of virtual sensor models.

10. The computing device of claim 1, wherein:
the greenhouse gas emissions estimate indicates a predicted amount of a greenhouse gas emission associated with a transaction; and
the greenhouse gas emissions estimate is conveyed to the user interface prior to the user performing the transaction.

11. The computing device of claim 1, wherein the processor is further configured to:
select a recommended action based at least in part on the greenhouse gas emissions estimate; and
convey an indication of the recommended action to the user interface for output on the one or more output devices.

12. The computing device of claim 1, wherein the processor is further configured to:
programmatically determine an industrial hardware control operation based at least in part on the greenhouse gas emissions estimate; and
output instructions to perform the industrial hardware control operation to one or more industrial hardware control devices.

13. A method for use with a computing device, the method comprising:
for one or more emissions factors, receiving respective emissions factor data including sensor data received from one or more sensors and user-specified data received at a user interface;
receiving a plurality of virtual sensor models via an application program interface (API), wherein each virtual sensor model of the plurality of virtual sensor models includes one or more respective virtual sensor model parameters and is configured to process the emissions factor data;
at least in part by applying the plurality of virtual sensor models to the emissions factor data, computing a plurality of virtual sensor readouts;
generating a greenhouse gas emissions estimate from the plurality of virtual sensor readouts; and
conveying an indication of the greenhouse gas emissions estimate to the user interface for output on one or more output devices.

14. The method of claim 13, further comprising storing a ledger including the plurality of virtual sensor readouts and corresponding virtual sensor readout timestamps.

15. The method of claim 14, further comprising:
receiving a virtual sensor model update via the API;
modifying a virtual sensor model of the plurality of virtual sensor models as specified by the virtual sensor model update; and
in response to modifying the virtual sensor model, storing, in the ledger, a virtual sensor modification record and a virtual sensor modification timestamp corresponding to the virtual sensor model update.

16. The method of claim 13, wherein the one or more sensors include one or more physical sensors and one or more additional virtual sensor models.

17. The method of claim 13, wherein at least one virtual sensor model of the plurality of virtual sensor models is a machine learning model.

18. The method of claim 13, wherein:
the plurality of virtual sensor models are received from a model specifier computing device that differs from the client computing device; and
the client computing device is prevented from modifying the respective virtual sensor model parameters of the plurality of virtual sensor models.

19. The method of claim 13, wherein:
the greenhouse gas emissions estimate indicates a predicted amount of a greenhouse gas emission associated with a transaction; and
the greenhouse gas emissions estimate is conveyed to the user interface prior to the user performing the transaction.

20. A computing device comprising:
memory; and
a processor configured to:
for one or more emissions factors, receive respective emissions factor data including sensor data received from one or more sensors and user-specified data received at a user interface;
receive a virtual sensor model, wherein the virtual sensor model includes one or more respective virtual sensor model parameters and is configured to process the emissions factor data;
at least in part by applying the virtual sensor model to the emissions factor data, compute a virtual sensor readout;
generate a greenhouse gas emissions estimate from the virtual sensor readout;
store, in the memory, a ledger including the virtual sensor readout and a corresponding virtual sensor readout timestamp;
convey the virtual sensor readout and the virtual sensor readout timestamp to the user interface for output on one or more output devices.
